(19) United States
(12) Patent Application Publication
(10) Pub. No.: US 2008/0102553 A1
(43) Pub. Date: May 1, 2008

(54) STABILIZING AN OPENED CARBON HARDMASK

(75) Inventors: TAEHO SHIN, San Jose, CA (US); Ajey M. Joshi, San Jose, CA (US); Zhuang Li, San Jose, CA (US); Wei-Te Wu, Cupertino, CA (US); Jin Chul Son, Wha-Sung Si (KR); Jong Hun Choi, Kung Won (KR)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc., Santa Clara, CA (US)

(21) Appl. No.: 11/555,160

(22) Filed: Oct. 31, 2006

(51) Int. Cl. H01L 21/00

(52) U.S. Cl. 438/70

(57) ABSTRACT

A process for passivating a carbon-based hard mask, for example, of hydrogenated amorphous carbon, overlying an oxide dielectric which is to be later etched according to the pattern of the hard mask. After the hard mask is photo lithographically etched, it is exposed to a plasma of a hydrogen-containing reducing gas, preferably hydrogen gas, and a fluorocarbon gas, preferably trifluoromethane. The substrate can then be exposed to air without the moisture condensing in the etched apertures of the hard mask.

### FIELD OF THE INVENTION

The invention relates generally to etching of semiconductor integrated circuits. In particular, the invention relates to the formation of etching hard masks principally containing carbon and hydrogen.

### BACKGROUND ART

Plasma etching is one process used in the definition of the structure of a silicon integrated circuit. One example involves the etching of via holes through a dielectric layer to form a vertical metallic interconnect structure, which in some advanced designs, may simultaneously form the horizontal interconnect structure. The dielectric layer is conventionally formed of a material based on silicon dioxide, also called oxide. More advanced dielectrics have included fluorine or other dopants to reduce the dielectric constant. Yet other dielectric compositions may be used. The conventional and long established photo lithographic process deposits a generally layer of photoresist material onto the unpatterned oxide with perhaps an anti-reflective coating (ARC) therebetween. The photoresist is optically patterned according to a desired pattern and then developed to remove the unexposed photoresist in positive lithography or exposed photoresist in negative lithography. The patterned photoresist then serves as a mask for a further step of etching the exposed oxide and intermediate ARC if present. Dielectric etch processes have been developed which provide a reasonable etch selectivity between the oxide and photoresist.

The advance of integrated circuit technology has depended in large part on the continuing shrinkage of the horizontal features such as the via holes through the oxide layer. Via widths are now decreasing to below 100 nm. However, because of considerations such as dielectric breakdown and cross tall, the oxide thickness has held steady at around 1 μm and there are many structures in which oxide thicknesses of 3 μm or more are desired. Such high aspect ratios of the holes to be etched in the oxide layer have presented several problems between the photolithography and the etching. To maintain depth of field in the optical patterning, the thickness of the photoresist should be not much greater than the size of the feature being defined in the oxide layer, e.g., a few hundred nanometers in the above example. As a result, the etch selectivity, that is, the ratio of the oxide etch rate to the photoresist etch rate should be significantly greater than 10 if the mask is to remain until the via hole has been etched to its bottom. However, photoresists are typically based on soft organic polymeric materials. Obtaining such high selectivity of photoresist has been difficult to achieve while simultaneously achieving other requirements such as vertical profiles in the narrow via holes.

Further, it is desired that the lithography for exposing the photoresist with 248 nm radiation produced by a KrF laser be transitioned to 193 nm radiation produced by an ArF laser. However, the 193 nm radiation presents further problems. Photoresist which is sensitive to the shorter wavelengths is generally a softer material and the maximum thickness of the photoresist is generally reduced to less than 400 nm to accommodate the shallower depth of field at the shorter wavelength.

An example of a via structure is a contact via illustrated in FIG. 1. Over a silicon substrate 12 is deposited an etch stop layer 14, for example, of silicon nitride. A dielectric layer 16 is deposited over the etch stop layer 14. Photo lithographic patterning forms a via hole 18 down to the silicon substrate 12. Contact and metallization metals as well as barrier layers are then filled into the via hole 18 to electrically contact the underlying silicon layer 12 to a wiring layer on top of the dielectric layer 16. Inter-metal via structures are similar in which the underlying layer is not silicon but a lower metal layer. Also, more complex inter-level structures such as dual-damascene are widely used. Previously, a photoresist etch mask was sufficient to mask the etching of a via hole having a relatively high aspect ratio. However, photoresist etch masks have proved insufficient for advanced integrated circuits, which require a thinner photoresist layer to maintain the critical dimension (CD) of narrow via holes. Adequate selectivity to such a thin layer of photoresist has been difficult to achieve.

Accordingly, many advanced devices rely upon an amorphous carbon hard mask 20, which is overlain by a anti-reflection coating 22, typically composed of silicon oxynitride (SiON) and a topmost photoresist layer 24. The photoresist layer 24 is photographically patterned into a photomask, which masks the opening (etching) of the anti-reflection coating 22 and the etching of the hard mask 20. Once the hard mask 20 has been etched, the photomask is no longer required and the etching chemistry may be changed to provide better selectivity between the dielectric layer 16 and the hard mask 20 and to produce a vertical etching profile. At the completion of dielectric etching, the hard mask 22 is usually removed. An oxygen plasma is effective at removing a carbon-based hard mask. The oxide-based dielectric layer 16 is typically etched with a fluorocarbon-based plasma, for example, using CF₄, CHF₃, CH₂F₂, C₄F₆, etc. as the main etching gas.

Similar structures are used for inter-level metallization, which contact a conductive feature in a lower-level dielectric layer or an active silicon region. In the former case especially for copper metallization, the via hole may be replaced a dual-damascene structure having a lower via structure used for a vertical interconnect and an upper trench structure used for a horizontal interconnect, which are both filled with copper.

Hard masks are needed in dielectric etching as the feature size decreases to less than 100 nm and using 193 nm photoresist patterning radiation available from an ArF laser. Hard masks have been proposed in the past, typically composed of silicon nitride or silicon dioxide or oxynitride. However, these traditional hard mask material have some limitations such as selectivity, growth thickness, and particularly for low-k interlevel dielectrics the need to hard mask that more resembles organic photoresist. A particularly advantageous hard mask material is a carbon-based material such as Advanced Patterning Film (APF) available from Applied Materials, Inc. of Santa Clara, Calif. Its deposition by plasma enhanced chemical vapor deposition (PECVD) has been described by Fairbairn et al., in U.S. Pat. No. 6,573,030 using a hydrocarbon, for example, propylene (C₃H₆), as a precursor. Wang et al. in U.S. Published Application 2005/0199585 and Liu et al. in U.S. Published Application 2005/0167394 have described its use as a hard mask. These three documents are incorporated herein by reference. Fairbairn has characterized this material as being composed of at least 40 at % of carbon and between 10 and 60 at % of hydrogen. A tighter compositional range is, however, preferred, of at least 60 at % of carbon and between 10 and 40 at % of hydrogen. Dopants have been proposed to control the dielectric constant and refractive index, but an APF hard mask patterned through an effective anti-reflective coating does not seem to require substantial components other than carbon and hydrogen. APF material is believed to form as an amorphous material although its growth condition and precursors may change the crystallography. APF grown at 400° C. has been observed to have a density of 1.1 g/cm², a hardness of 2.2 MPa, a strength of 2.2 MPa, and an optimized C/H atomic ratio of 63/37. The ratio of single hydrocarbon bonds (C—H) to double hydrocarbon bonds (C═H) is observed to be about 5. Recently developed APF films grown at higher temperatures may show somewhat different characteristics.

Often separate etch chambers are used for etching the hard mask and etching the dielectric. Often also the wafer is removed from the vacuum chamber and stored at ambient for extended periods of time between the two etching steps because of scheduling constraints. Even two hours of waiting in clean dry ambient between platforms has been observed to introduce problems in this type of processing. Sometimes, a fraction of the partially developed via holes are observed to fill with some substance which interferes with subsequent processing. Cleaning the wafer with plasmas of argon, oxygen, or carbon tetrachloride (CF₄) or extended pump down has not been effective at emptying the via holes.

We have observed that focusing the electron beam of a scanning electron microscope (SEM), which is often used to monitor the critical dimension (CD) during processing, removes the substance. Accordingly, we believe that the substance is based on water (H₂O) although it may be in the form of a water-based polymer. Clearly, this water condensate either should be repressed or be removed. Attempts to modify the hard mask etch to prevent the subsequent condensation have been unsuccessful.

### SUMMARY OF THE INVENTION

A carbon-based hard mask, for example, of amorphous carbon hard mask, for use as an etching mask of an underlying layer comprises at least 40 at % carbon and between 10 and 40 at % hydrogen, more preferably at least 60 at % carbon and between 10 and 40 at % hydrogen. After the hard mask is photo lithographically patterned, it is passivated by being subject to a plasma of a hydrogen-containing reducing gas and a fluorocarbon. The preferred reducing gas is hydrogen gas. The fluorocarbon may be a hydrofluorocarbon, preferably a fluoromethane, more preferably trifluoromethane.

The passivation etch is a soft etch in which the pedestal electrode supporting the substrate is biased significantly less if at all than during the hard mask etch.

The passivation prevents water from developing and filling the hard mask aperture when it is exposed to air.

### BRIEF DESCRIPTION OF THE DRAWINGS

FIG. 1 is a cross-sectional view of a conventional inter-level via structure.

FIG. 2 is a cross-sectional view of the structure of an opened hard mask.

FIG. 3 is a schematic cross-sectional view of the chemical bonding at the surface of a passivation layer.

FIG. 3 is a schematic cross-sectional view showing the intermediate effect of exposing the passivation layer to air.

FIG. 4 is a schematic cross-sectional view showing the water condensate resulting from exposing the passivation layer to air.

FIG. 5 is a schematic cross-sectional view showing the chemical bonding resulting from stabilizing the passivation film according to one embodiment of the invention.

FIG. 7 is a schematic cross-sectional view of a plasma etch reactor in which the invention may be practiced.

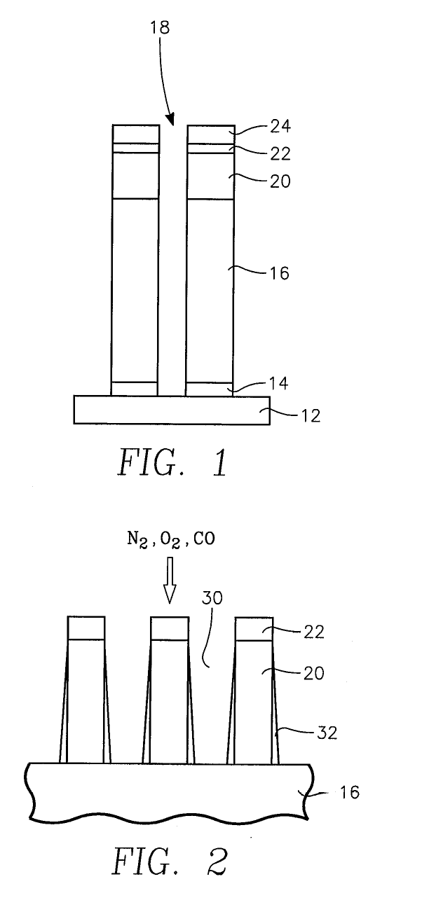

### DETAILED DESCRIPTION OF THE PREFERRED EMBODIMENTS

Although the invention is not limited to our understanding of its operation, we believe that the water condensation arises from the interaction of air, specifically gaseous oxygen O₂, and the passivation film formed in the etching of the carbon-based hard mask. The hard mask layer is typically formed of amorphous carbon (a-C) such as the previously described Advanced Patterning Film (APF) available from Applied Materials. APF is mainly composed of carbon and hydrogen. One typical etching recipe for APF is an etching gas composed of carbon monoxide (CO), nitrogen gas (N₂) and oxygen gas (O₂), which is excited into a plasma in a plasma etch chamber. An alternative chemistry uses an etching gas of hydrogen gas (H₂), nitrogen gas, and carbon monoxide, as described by Wang et al. in U.S. patent application Ser. No. 11/244,422, filed Oct. 5, 2005.

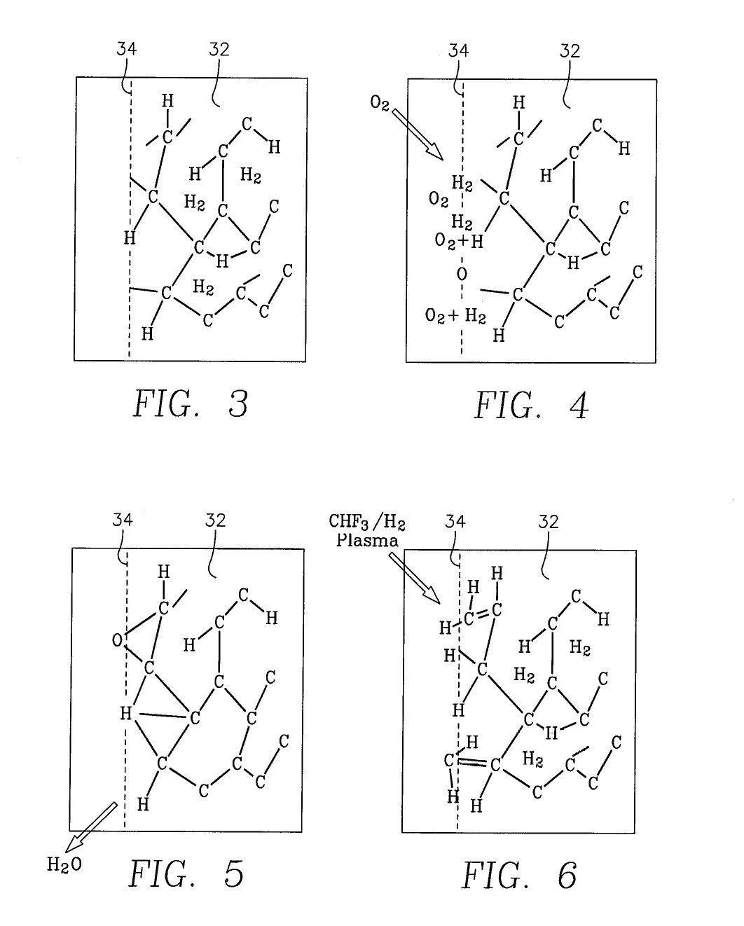

As illustrated in the cross-sectional view of FIG. 2, after the anti-reflection layer 22 is opened, the APF etch produces a highly anisotropic mask aperture 30 in the APF hard mask 20 and is selective to the underlying oxide layer 16. The anisotropy is accomplished in large part by the formation of a passivation layer 32 on the sidewalls of the developing hard mask aperture 30. The passivation layer 32 is believed to be composed principally composed of a hydrocarbon polymer, probably with the addition of elemental oxygen and possibly other constituents. We believe that the passivation layer 32, as illustrated in the schematic cross-sectional view of FIG. 3, includes dangling carbon bonds at a surface 34 of the passivation film 32, corresponding to the sidewall of the mask aperture 30, because of under-coordinated carbon atoms near the surface 34. Also, the passivation film 32 is believed to contain molecular hydrogen (H₂).

As illustrated in the schematic cross-sectional view of FIG. 4, the molecular hydrogen is believed over time to diffuse to the surface 34. When the wafer is exposed to air, specifically molecular oxygen (O₂), the molecular hydrogen at the surface 34 tends to react and dissociate the molecular oxygen to form, as illustrated in the schematic cross-sectional view of FIG. 5, molecular water (H₂O). The polar molecular water can stick on the sidewall surface 34 to form a film of water. The water film may form as a polymer with remaining dangling bonds of different components at the surface 34 of the passivation film 32. The thickening water film can be viewed as water condensing on the walls of the already formed mask aperture 30. The condensation can grow and fill the mask aperture 30. The condensation appears to adhere well to the hydrocarbon polymer of the passivation film 32 so that it remains even when exposed to a deep vacuum. The aqueous composition of the material plugging the mask aperture 30 explains why plasmas of argon, oxygen, and carbon tetrafluoride were observed to be ineffective at removing it since these excited species do not produce a passivating layer which blocks the diffusion of hydrogen from the APF film.

We have found that water condensation can be eliminated by a plasma stabilization step after the hard mask opening. The plasma gas preferably contains both hydrogen and carbon. We have found that a combination of trifluoromethane (CHF₃) and hydrogen gas (H₂) is effective. We believe that the CHF₃/H₂ plasma, as illustrated in the schematic cross-sectional view of FIG. 6, reacts with the dangling hydrogen bonds at the passivation surface 34 to form a stabilized hydrocarbon film of somewhat indeterminate composition of approximately CₓH_{y}. The hydrocarbon film prevents the diffusion of additional molecular hydrogen to the surface. Furthermore, the hydrocarbon film is sufficiently stable in the presence of molecular oxygen to prevent any reaction of the oxygen with the passivation film 32 which would produce significant number of water molecules. That is, the stabilized passivation layer prevents the formation of significant water film.

Hydrogen gas may be replaced by other hydrogen-containing reducing gases such as NH₃. Trifluoromethane may be replaced by other fluorocarbons or hydrofluorocarbons, which as a class are known to promote the formation of a carbonaceous polymer. Difluoromethane (CH₂F₂) and monofluoromethane (CH₃F) are preferred substitute hydrofluorocarbons

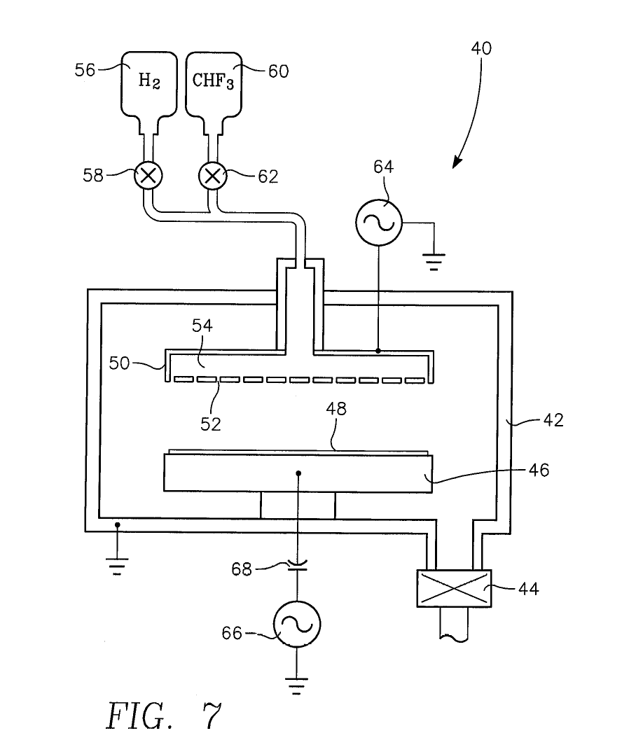

The stabilization process may be performed in the same etch reactor used to open the amorphous carbon hard mask. A plasma etch reactor 40 schematically illustrated in the cross-sectional view of FIG. 7 is a capacitively coupled diode reactor, such as is commercially available from Applied Materials, Inc. of Santa Clara, Calif. as the eMax etch reactor. The etch reactor 40 includes a vacuum chamber 42 which is electrically grounded and is vacuum pumped by a pump system 44 to low pressures in the milliTorr range. A pedestal electrode 46 chamber 42 supports a wafer 48 to be processed within the vacuum chamber 42. A showerhead electrode 50 in opposition to the pedestal electrode 46 includes a large number of apertures 52 on its front face supplying processing gas from a gas manifold 54 so that an even gas flow is presented to the wafer 48. Processing gases are separately metered from typically more than one gas source into the gas manifold 54 and mixed therein. In the sample recipe presented below, hydrogen gas (H₂) is supplied from a hydrogen gas source 56 and its flow is controlled by a first mass flow controller 58 and trifluoromethane (CHF₃) is supplied from a fluorocarbon gas source 60 and its flow is controlled by a second mass flow controller 62.

A source RF power supply 64, for example, operating at 13.56 MHz applies RF source power to the showerhead electrode 50 in opposition to the grounded wall of the vacuum chamber 42 to excite the processing gas within the vacuum chamber 42 into a plasma. A bias RF power supply 66, for example, operating at between 1 and 2 MHz applies RF bias power through a capacitive coupling circuit 68 to the pedestal electrode 46 to develop a negative DC self-bias on the pedestal electrode 46 with respect to the adjacent plasma. The negative bias is effective at attracting and accelerating positive ions in the plasma to the wafer 48. The energetic ions are more effective at sputter etching the wafer 48 and at penetrating into high aspect-ratio holes, such as vias, formed in the surface of the wafer 48. The eMax chamber is additionally equipped with a set of magnetic coils to effect magnetically enhanced reactive ion etching (MERIE); but the coils are not used in the recipe which has been developed to date for the invention.

A sample recipe for an integrated etch process including ARC open, hard mask etch and post-etch stabilization is summarized in TABLE 1.

TABLE 1

| Parameter | ARC | APF | PET |
|---|---|---|---|
| CF₄ | 80 | | |
| CHF₃ | 20 | | 200 |
| CO | | 75 | |
| N₂ | | 60 | |
| O₂ | | 35 | |
| H₂ | | | 50 |
| Pressure | 50 | 15 | 200 |
| Source Power | | 1600 | 1000 |
| Bias Power | 300 | 600 | 100 |
| Time | 60 | 25 | 10 |

The gas flows for the five listed gases are in units of sccm; the pressure, in milliTorr; the powers, in watts, all for a chamber sized for a 200 mm wafer; and time, in seconds. The recipe includes three steps for opening the anti-reflection coating (ARC), opening the carbon-based hard mask (APF), and the stabilization or post-etch treatment (PET). It is understood that the reactor 40 is additionally equipped with added gas supplies and associated mass flow controllers for the three gases used only in the ARC and APF steps.

The stabilization step of this embodiment may be characterized as using an etching gas composed of hydrogen-containing reducing gas, especially hydrogen gas, and a hydrofluorocarbon. The source power is decreased somewhat from that used for the hard mask etch. The bias power is significantly reduced since no anisotropic etching is desired but some bias power pulls etching ions into the high aspect-ratio hard mask apertures.

The invention is not limited to illustrated diode reactor but may be practiced in other plasma etch reactors including ones with inductively coupled power or utilizing a remote plasma source.

The invention is further not limited to APF films or to hard masks.

The stabilization process enabled by the invention eliminates a significant problem in the etching of advanced integrated circuits with little impact on either cost or throughput.

1. A process for passivating a hole in a carbon-based layer formed in the surface of a substrate and comprising at least 40 at % of carbon and between 10 and 60 at % of hydrogen, comprising subjecting the substrate to a plasma of an etching gas comprising hydrogen-containing reducing gas and a fluorocarbon gas.

2. The process of claim 1, wherein the carbon-based layer comprises at least 60 at % carbon and between 10 and 40 at % of hydrogen.

3. The process of claim 1, wherein the fluorocarbon gas comprises a hydrofluorocarbon gas.

4. The process of claim 1, wherein the hydrofluorocarbon gas comprises a fluoromethane.

5. The process of claim 4, wherein the fluoromethane comprises trifluoromethane.

6. The process of claim 5, wherein the reducing gas comprises hydrogen gas.

7. The process of claim 1, wherein the reducing gas comprises hydrogen gas.

8. The process of claim 1, wherein the carbon-based layer overlies a dielectric layer comprising silicon oxide.

9. The process of claim 8, wherein the aperture extends down to the dielectric layer.

10. The process of claim 1, further comprising:
plasma etching the carbon-based region with a plasma of an etching gas and including the bias RF power supply applying a first level of RF power to the pedestal electrode;
wherein the subject step includes the bias RF power supply applying a second level of RF power less than half the first level to the pedestal electrode.

11. A process for etching an aperture in a structure comprising a carbon-based layer overlying a silicon oxide layer performed in a plasma etch chamber including a pedestal electrode for supporting the structure, comprising the steps of:
a first step of exciting a first etching gas into a plasma to etch the carbon-based layer to create a hole; and
then a second step of exciting a passivating gas into a plasma, the passivating gas comprising a hydrogen-containing reducing gas and a fluorocarbon gas.

12. The process of claim 11, further comprising exposing the structure to atmospheric oxygen before the silicon oxide layer at the bottom of the hole is etched through.

13. The process of claim 11, further comprising etching through the silicon oxide layer with a plasma of a second etching gas.

14. The process of claim 10, wherein a first level of RF power is applied to the pedestal electrode in the first step and a second level of RF power less than 50% of the first level is applied to the pedestal electrode in the second step.

15. The process of claim 11, wherein the carbon-based material comprises at least 40 at % carbon and between 10 and 60 at % hydrogen.

16. The process of claim 11, wherein the hydrogen-containing reducing gas comprises ammonia.

17. The process of claim 11, wherein the hydrogen-containing reducing gas comprises hydrogen gas.

18. The process of claim 17, wherein the fluorocarbon gas comprises a fluoromethane.

19. The process of claim 18, wherein the fluoromethane comprises trifluoromethane.
